(19) United States
(12) Patent Application Publication
(10) Pub. No.: US 2023/0396934 A1
(43) Pub. Date: Dec. 7, 2023

(54) OPTICAL ACOUSTIC SENSOR

(71) Applicant: ams International AG, JONA (CH)

(72) Inventors: Goran STOJANOVIC, Rapperswil (CH); Pierre Jean-Francois SEURIN, Princeton Junction, NJ (US); Guoyang XU, Newtown, PA (US); Haisong WANG, Bear, DE (US); Peng GAO, Princeton, NJ (US)

(73) Assignee: ams International AG, JONA (CH)

(21) Appl. No.: 18/249,398

(22) PCT Filed: Oct. 21, 2021
(86) PCT No.: PCT/EP2021/079193

§ 371 Date: Apr. 18, 2023

(30) Foreign Application Priority Data
Oct. 23, 2020 (GB) 2016827.4

(51) Int. Cl. H04R 23/00; H04R 1/04; H04R 31/00; H04R 29/00; H04R 7/04; H01S 5/183

(52) U.S. Cl. CPC H04R 23/008; H04R 1/04; H04R 31/006; H04R 29/004; H04R 7/04; H01S 5/18363; H04R 2201/003

(57) ABSTRACT

An acoustic sensor is disclosed, the sensor including a laser and a membrane configured to vibrate in the presence of an acoustic wave, and to reflect radiation emitted by the laser back toward the laser to produce a self-mixing interference effect corresponding to the acoustic wave. The sensor also includes a cavity separating the membrane from the laser and extending rearward of a radiation-emitting surface of the laser, a majority volume of the cavity being disposed rearward of the radiation-emitting surface of the laser. Also disclosed is an apparatus including the acoustic sensor, and a method of manufacturing the acoustic sensor.

### CROSS-REFERENCE TO RELATED APPLICATIONS

The present application is the national stage entry of International Patent Application No. PCT/EP2021/079193, filed on Oct. 21, 2021, and published as WO 2022/084443 A1 on Apr. 28, 2022, which claims the benefit of priority of Great Britain Patent Application No. 2016827.4, filed on Oct. 23, 2020, the disclosures of all of which are incorporated by reference herein in their entireties.

### TECHNICAL FIELD OF THE DISCLOSURE

The present disclosure is in the field of acoustic sensors, and particularly relates to micro-electromechanical system (MEMS) based acoustic sensors.

### BACKGROUND

Acoustic sensors may be implemented as microphones in a range of electronic devices such as portable computing devices, tablet devices, smart phones, and the like. Such acoustic sensors may be suitable for detecting acoustic waves, e.g. dynamic pressure changes in a surrounding environment. Typically, an acoustic sensor may be configured to sense acoustic waves in a surrounding environment over a particular acoustic frequency band.

Some acoustic sensors may be manufactured as micro-electromechanical systems (MEMS). For example, capacitive-type MEMs acoustic sensors are well known in the art. Such capacitive-type sensors may exhibit a relatively limited sensitivity, and hence a resultant signal-to-noise ratio may be unsuitable for some audio applications.

In recent years, acoustic sensors using optical devices for readout have been developed. Such optical device-based acoustic sensors may provide some advantages over conventional acoustic sensors in terms of increased sensitivity, increased frequency range, and reduced electronic and acoustic noise. However, such optical device-based acoustic sensors may also be inherently expensive and complex to manufacture, and may not be adequately compact for their target applications.

Acoustic sensors are generally becoming highly integrated components within electronic devices, wherein the acoustic sensors are provided with increasingly sophisticated package designs. Furthermore, stringent size constraints may be imposed upon such sensors particularly when used in mobile devices. As such, components required to manufacture acoustic sensors are required to be relatively small, such that a packaged acoustic sensor is sufficiently compact.

It is therefore desirable to provide a highly sensitive, low-cost, low-complexity and high reliability acoustic sensor, suitable for integration within electronic devices such as portable computing devices, tablet devices, smart phones, and the like.

It is therefore an aim of at least one embodiment of at least one aspect of the present disclosure to obviate or at least mitigate at least one of the above identified shortcomings of the prior art.

### SUMMARY

The present disclosure is in the field of acoustic sensors, and particularly relates to micro-electromechanical system (MEMS) based acoustic sensors for use in electronic devices such as portable computing devices, tablet devices, smart phones, and the like.

According to a first aspect of the disclosure, there is provided an acoustic sensor comprising a laser and a membrane configured to vibrate in the presence of an acoustic wave, and to reflect radiation emitted by the laser back toward the laser to produce a self-mixing interference (SMI) effect corresponding to the acoustic wave.

The acoustic sensor also comprises a cavity separating the membrane from the laser and extending rearward of a radiation-emitting surface of the laser, a majority volume of the cavity being disposed rearward of the radiation-emitting surface of the laser.

Advantageously, provision of a majority volume of the cavity being disposed rearward of the radiation-emitting surface of the laser enables implementation of a cavity providing a sufficient acoustic capacitance, but without requiring location of the membrane a substantial distance from the radiation-emitting surface of the laser to achieve the sufficiently large cavity. A sufficiently large acoustic capacitance is a requirement of such acoustic sensors to provide adequate sensitivity, and thus meet signal-to-noise ratio requirements. Advantageously, a larger acoustic capacitance of the air behind the membrane may lead to a reduction in an acoustic damping or acoustic resistance which is induced by the limited compressibility of the air within the cavity.

Advantageously, because the provision of a majority volume of the cavity being disposed rearward of the radiation-emitting surface of the laser enables location of the membrane to be relatively close to the radiation-emitting surface of the laser, relatively high junction voltage variations due to the self-mixing interference effect may be achieved. The higher junction voltages may improve a signal level, and thus a signal-to-noise ratio, of the acoustic sensor. For example, in some embodiments the acoustic sensor may be configured to provide a signal in the range of 10 mV peak for a 1 Pa sound pressure level.

If a relatively large distance was to be implemented between the radiation-emitting surface of the laser and the membrane, then due to a non-ideal collimation of radiation emitted by the laser, the radiation may be insufficiently focused upon a reflective portion of the membrane. Therefore, not all of the emitted radiation would be reflected back into the laser to produce the necessary self-mixing interference effect. That is, in order to have a sufficient self-mixing interference effect, reflectivity of the membrane should be in the region of 90% or higher.

Advantageously, by keeping a distance between the laser and membrane relatively small, as enabled by the provision of the majority of the cavity extending rearward of the radiation-emitting surface of the laser, a greater proportion of radiation emitted by the laser may be reflected back into the laser to provide the self-mixing interference effect.

A gap between the membrane and the radiation-emitting surface of the laser may be 50 micrometers or less.

In some embodiments the gap between the membrane and the radiation-emitting surface of the laser may be in the range of 50 to 10 micrometers. In some embodiments, the gap between the membrane and the radiation-emitting surface of the laser may be approximately 12 micrometers.

Advantageously, a reduced distance between the membrane and the radiation-emitting surface of the laser may improve acoustic damping characteristics of the gap between the laser and the membrane. That is, air within the gap may exhibit an acoustic impedance, e.g. an effective resistance to being compressed, which may have the effect of improving a frequency response of the acoustic sensors. For example, a higher acoustic impedance in the gap due to a close proximity of the membrane to the laser may help prevent unwanted oscillations in the membrane at particular frequencies.

Furthermore, as described above, a gap in the region of 50 micrometers or less may advantageously improve an overall signal-to-noise ratio of the sensor because of an increased junction voltage incurred due to a greater proportion of radiation emitted by the laser being reflected back into the laser to provide the self-mixing interference effect. Furthermore, due to the selected dimensions of the gap, an acoustic resistance, e.g. damping effect of the air in the gap between the membrane and the radiation-emitting surface of the laser, will not be a dominant noise source in a system comprising the acoustic sensor, yet the particular construction enables sufficient choices in the size of the gap between membrane and the radiation-emitting surface of the laser.

The laser may be configured such that a junction voltage of the laser corresponds to the acoustic wave due to the self-mixing interference effect.

As such, the laser may be implemented a laser diode. The junction voltage of the laser may be measureable at nodes or contacts provided on, or electrically coupled to, the laser.

Advantageously, use of the self-mixing interference effect may enable efficient determination of characteristics of the acoustic wave, such as frequency and amplitude. Furthermore, use of the self-mixing interference effect to provide a measureable junction voltage indicative of characteristics of the acoustic wave obviates a necessity to implement separate sensors, such as separate photodiodes, for detection of radiation reflected by, or propagated through, the membrane.

In some instances a photonics power of radiation emitted by the laser, e.g. the VCSEL, may be readout using a photodiode disposed next to, adjacent, or below the laser. Advantageously, by having the membrane relatively close to the laser, a power of reflected radiation detected by the photodiode may be adequately high to provide a sufficient SNR.

The acoustic sensor may comprise circuitry coupled to the laser and configured to sense the junction voltage.

The circuitry may comprise an analogue-to-digital converted. The circuitry may comprise an amplifier. The circuitry may comprise, or be implemented on, an Application-Specific Integrated Circuit (ASIC). The circuitry may comprise a biasing circuit, e.g. a VCSEL biasing circuit. The circuitry may comprise processing circuitry, such as circuitry configured to enable readout of the SMI. That is, circuitry may be configured to provide data or a signal corresponding to the SMI effect.

Advantageously, due to a relatively small footprint of the acoustic sensor due to the provision of the majority volume of the cavity being disposed rearward of the radiation-emitting surface of the laser, the acoustic sensor may be provided as a packaged module comprising the circuitry. In some embodiments, a PCB that functions as a substrate for coupling to the laser or to the membrane may also comprise the circuitry configured to sense the junction voltage.

In some embodiments, the circuitry coupled to the laser and configured to sense the junction voltage may be provided as part of, or integrated into, a driver circuit for driving the laser.

The acoustic sensor may comprise a first substrate. The laser may be electrically coupled to the first substrate.

In some embodiments, the laser may be electrically coupled to the first substrate using bond wires. In some embodiments, the laser may be electrically coupled, e.g. soldered, to bond pads or vias implemented on the substrate.

Advantageously, the substrate may provide a means to electrically couple the laser to driver circuitry for driving the laser and/or circuitry for sensing the junction voltage, and also a means to support the laser and/or the membrane relative to one another, e.g. to provide the gap between the membrane and the laser.

The laser may be formed on the first substrate.

The laser may be a semiconductor laser that is formed, such as lithographically formed or epitaxially grown, directly onto the first substrate. Thus, the first substrate may advantageously provide a base substrate for the laser in addition to forming at least a portion of the cavity. As such, the laser may be highly integrated into the acoustic sensor, providing a reduced overall sensors size and/or footprint. Furthermore, in such embodiments, manufacturing efficiencies may be realized through an overall reduction in device assembly steps.

The laser may be mounted on the first substrate.

In some embodiments the laser may be manufactured using a particular semiconductor process, e.g. GaAs, and mounted on a separate first substrate that is not for use in the same process, e.g. a silicon substrate or an FR-4 PCB substrate. As such, an overall cost-effectiveness of the acoustic sensor may be optimized.

The membrane may be disposed between an aperture, known in the art as a ‘sound port’, in the first substrate and the radiation-emitting surface of the laser.

The aperture may allow acoustic waves to be incident upon the membrane. As such, the first substrate may form a portion of the cavity that encloses the laser, yet also provide means for acoustic waves to be incident upon the membrane.

In some embodiments, a diameter of the aperture may correspond to an effective diameter of the membrane.

The acoustic sensor may comprise an enclosure. The enclosure may be acoustically sealed to the first substrate. The enclosure may enclose the laser. The enclosure may define the cavity.

The enclosure may be implemented as a can package, such as a metal can package. The enclosure may be a canister or housing.

An acoustic seal may be formed from a sealing ring or gasket disposed between the enclosure and the first substrate. The acoustic seal may be formed from an adhesive. In some embodiments, the enclosure may be soldered to the first substrate to form the acoustic seal.

The substrate may comprise a recess surrounding the laser and defining the cavity.

The recess may be etched into the substrate. The recess may be formed by means of a lithographic process. The recess may be cut or ground into the substrate.

The substrate may comprise a mesa supporting the laser and at least in part defining the cavity. The mesa may be a raised section of the substrate. The mesa may form a pedestal.

The mesa, or pedestal, may be formed by etching a region surrounding the mesa by means of a lithographic process. The mesa, or pedestal, may be cut or ground into the substrate.

The first substrate may be coupled to a second substrate. A first portion of the cavity may be between the membrane and the first substrate. A second portion of the cavity may be defined by a recess in the second substrate. The first portion of the cavity may be communicably coupled to the second portion of the cavity by at least one opening in the first substrate.

Advantageously, the at least one opening may provide one or more conduits for airflow through the first substrate. As such, the opening may enable the first and second portions of the cavity to operate collectively as a single cavity for providing adequate acoustic capacitance for the acoustic sensor.

The laser may be suspended or supported between the membrane and a portion of the cavity that is rearward of the laser, by an apertured substrate.

The apertured substrate may provide one or more conduits for airflow. As such, the apertured substrate may enable the portion of the cavity that is rearward of the laser to be coupled to a portion of the cavity that is between the laser and the membrane, thus providing adequate acoustic capacitance for the acoustic sensor

The laser may be a vertical cavity surface-emitting laser (VCSEL).

Advantageously, a VCSEL-based self-mixing interference effect using the laser junction voltage as the source of the self-mixing signal may result in cost-savings and reductions in component costs and complexity, when compared to acoustic sensors employing photodiodes, or other discrete sensors for detecting reflections and/or transmission through the membrane.

The membrane may comprise a stretched film provided under tension.

Advantageously, the membrane does not need to be formed as a raised microstructure. The membrane may have a diameter of less than 300 micrometers. The membrane may have a diameter of approximately 270 micrometers.

The membrane may have a thickness of less than 100 nanometers. In some embodiments, a thickness of the membrane may be between 50 nm and 100 nm.

The membrane may comprise a reflector. A diameter of the reflector may be less than 100 micrometers. The reflector may be for reflecting radiation emitted by the laser.

In some embodiments, a diameter of the reflector may be in the range of 30 to 60 micrometers.

The reflector may be a mirror. By providing a majority volume of the cavity being disposed rearward of the radiation-emitting surface of the laser, the membrane may be disposed relatively close to the laser and thus even when accounting for a non-ideal collimation of radiation emitted by the laser, the reflector may be made relatively small, e.g. less than 100 micrometers in diameter.

Furthermore, the provision of a relatively small reflector, e.g. with a diameter of than 100 micrometers, may minimize a mass of the reflector. Thus, an overall mass of the combination of the membrane and the reflector may be minimized, which may advantageously reduce the effects of acoustic noise and increase membrane elasticity.

In some embodiments the reflector may be disposed on a surface of the membrane that is opposing the radiation-emitting surface of the laser.

In some embodiments the reflector may be disposed on an outer surface of the membrane, e.g. an opposite surface of the membrane to the surface of the membrane that is opposing the radiation-emitting surface of the laser. In such embodiments, the membrane may be substantially transparent to radiation emitted by the laser.

In some embodiments, the reflector may be embedded within the membrane. For example, in some embodiments the reflector may be formed as an integral component of the membrane. In some embodiments, the reflector may be disposed between layers of the membrane.

In some embodiments the reflector may comprise gold. In some embodiments the reflector may comprise aluminum.

In some embodiments the reflector may have a thickness in the range of 40 to 60 nanometers.

According to a second aspect of the disclosure, there is provided an apparatus comprising the acoustic sensor according to the first aspect, wherein the apparatus is one of: a smart speaker; a smart phone; a smart-watch; a laptop, a tablet device; or headphones.

According to a third aspect of the disclosure, there is provided a method of manufacturing an acoustic sensor, the method comprising: providing a laser and a membrane in a package such that the membrane is configured to vibrate in the presence of an acoustic wave and to reflect radiation emitted by the laser back toward the laser to produce a self-mixing interference effect corresponding to the acoustic wave; and providing the package with a cavity separating the membrane from the laser and extending rearward of a radiation-emitting surface of the laser, a majority volume of the cavity being disposed rearward of the radiation-emitting surface of the laser.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

These and other aspects of the present disclosure will now be described, by way of example only, with reference to the accompanying drawings, wherein:

FIG. 1 depicts a cross-sectional view of an acoustic sensor according to a first embodiment of the disclosure;

FIG. 2 depicts a cross-sectional view of an acoustic sensor according to a second embodiment of the disclosure;

FIG. 3a depicts a cross-sectional view of an acoustic sensor according to a third embodiment of the disclosure;

FIG. 3b depicts a top view of a substrate as implemented in the third embodiment depicted in FIG. 3a;

FIG. 4a depicts a cross-sectional view and a top view of corresponding top view of an acoustic sensor according to a fourth embodiment of the disclosure;

FIG. 4b depicts cross sectional views, a top view, and a partial perspective view of a VCSEL assembly for use in the acoustic sensor according to the fourth embodiment of the disclosure;

FIG. 4c depicts a further cross-sectional view of the acoustic sensor according to the fourth embodiment of the disclosure;

FIG. 5a depicts cross sectional views and a top view of a VCSEL assembly for use in an acoustic sensor according to a fifth embodiment of the disclosure;

FIG. 5b depicts a cross-sectional view and a corresponding top view of the acoustic sensor according to the fifth embodiment of the disclosure;

FIG. 5c depicts a further cross-sectional view of the acoustic sensor according to the fifth embodiment of the disclosure;

FIG. 6 an apparatus comprising an acoustic sensor according to an embodiment of the disclosure; and

FIG. 7 a method of manufacturing an acoustic sensor according to an embodiment of the invention.

### DETAILED DESCRIPTION

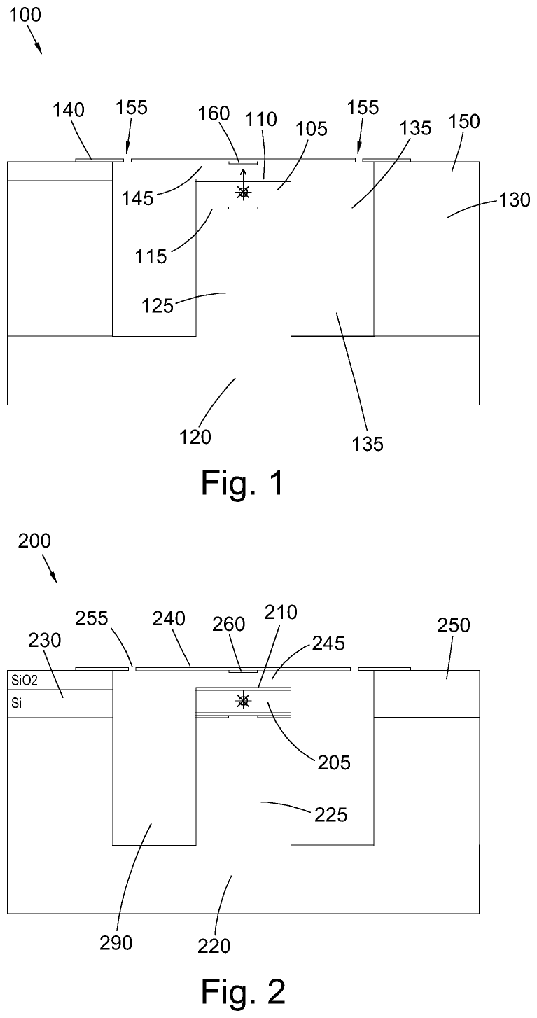

FIG. 1 depicts a cross-sectional view of an acoustic sensor 100 according to a first embodiment of the disclosure. The acoustic sensor 100 comprises a laser 105. In the example embodiment of FIG. 1, the laser 105 is a vertical-cavity surface emitting laser (VCSEL). It will be appreciated that in other embodiments, other laser diodes may be implemented.

The laser 105 is configured to emit radiation from a radiation-emitting surface 110 at a front of the laser 105, relative to a rear surface of the laser 105 comprising contacts 115 for providing electrical connectivity to the laser 105.

The acoustic sensor 100 comprises a first substrate 120. The first substrate 120 comprises a mesa 125, e.g. a pedestal, configured to support the laser 105. In some embodiments, the laser 105 may be formed on the mesa 125. In other embodiments, the laser 105 is provided as a discrete device which is adhered to the mesa 125 during an assembly process. The mesa 125 may, for example, be formed by etching the first substrate 120. Electrical contacts (not shown), formed from conductive traces and/or vias may be provided in/on the first substrate 120 to supply electrical current to the laser 105 and/or to provide means to sense a junction voltage of the laser 105, as described below in more detail.

The first substrate 120 may comprise glass, silicon, or the like.

The acoustic sensor 100 also comprises a second substrate 130. The second substrate 130 is formed with an aperture 135, such that the acoustic sensor 100 may be assembled with the mesa 125 of the first substrate 120 disposed within the aperture 135.

The second substrate 130 may comprise glass, silicon, or the like.

The acoustic sensor 100 also comprises a membrane 140. The membrane 140 is provided under tension. That is, the membrane 140 is provided as a stretched film provided under tension. The membrane 140 is secured to the second substrate 130 at at least a portion of a perimeter of the membrane 140. In some embodiments, the membrane 140 may comprise silicon nitride.

In some embodiments, the second substrate 130 may be a silicon substrate. In some embodiments, the second substrate 130 may comprise a layer 150 of silicon dioxide, and the membrane 140 may be secured, e.g. adhered or clamped, to the layer 150 of silicon dioxide.

The membrane 140 and the second substrate 130 may be provided as an assembly that is coupled, e.g. adhered, to the first substrate 120 during a process of assembly of the acoustic sensor 100.

The membrane 140 comprises a plurality of holes 155. The holes 155 extend between upper and lower surfaces of the membrane 140, thus providing through-passages in the membrane 140. In use, the holes 155 may act as pressure equalization holes. That is, static air pressure levels may typically fluctuate by several tens of hectoPascals at sea level. As sound pressure levels are in the order of 1 Pascal and can be as small as 20 microPascal, which is considered the threshold for human hearing, relatively equal pressure levels in the environment inside and outside the acoustic sensor 100 are necessary for the detection of vibrations of the membrane 140 incurred by small pressure fluctuations due to an acoustic wave.

The membrane 140 comprises a reflector 160.

The reflector 160 is disposed on a surface of the membrane 140 that is opposing the radiation-emitting surface 110 of the laser 105.

It will be appreciated that, in other embodiments falling within the scope of the disclosure, the reflector 160 may be disposed on an outer surface of the membrane 140, e.g. an opposite surface of the membrane 140 to the surface of the membrane 140 that is opposing the radiation-emitting surface 110 of the laser 105. In such embodiments, the membrane 140 may be substantially transparent to radiation emitted by the laser 105, such that radiation emitted by the laser 105 propagates through the membrane 140 and is reflected by the reflector back through the membrane towards the laser 105.

The reflector 160 is positioned on the membrane 140 relative to the laser 105 such that the reflector 160 reflects radiation emitted by the laser 105 back toward the laser 105 to produce a self-mixing interference effect, as described below in more detail.

In the example embodiment of FIG. 1, the reflector 160 has a diameter in the region of 100 micrometers. In some embodiments, a diameter of the reflector 160 may be less than 100 micrometers, e.g. in the range of 30 to 60 micrometers. The provision of a relatively small reflector 160, e.g. with a diameter of in the region of 100 micrometers or less, may minimize a mass of the reflector 160. Thus, an overall mass of the combination of the membrane 140 and the reflector 160 may be minimized, which may advantageously reduce the effects of acoustic noise and increase elasticity of the membrane 140.

The reflector 160 may be a mirror. The reflector 160 is configured to reflect radiation having a wavelength corresponding to wavelength of radiation emitted by the laser 105. In some embodiments, the reflector 160 may comprise gold. In some embodiments, the reflector 160 may comprise aluminum. The reflector 160 may be provided as a discrete element that is adhered to the membrane 140 during an assembly process. Alternatively, the reflector 160 may be formed on the membrane 140, e.g. by a process of deposition or the like.

A cavity 145 separates the membrane 140 from the laser 105 and extends rearward of the radiation-emitting surface 110 of the laser 105. A majority volume of the cavity 145 is disposed rearward of the radiation-emitting surface 110 of the laser 105. Advantageously, by providing a majority volume of the cavity 145 rearward of the radiation-emitting surface 110 of the laser 105, the membrane 140 may be disposed relatively close to the laser 105. Thus, even when accounting for a non-ideal collimation of radiation emitted by the laser 105, the reflector 160 may be made relatively small, e.g. less than 100 micrometers in diameter.

In the example embodiment of FIG. 1, the membrane 140 has a diameter in the region of 1.0 to 1.2 millimeters. In some embodiments, the reflector 160 may have a thickness in the range of 40 to 60 nanometers. In some embodiments, the reflector 160 may be as thick as 100 nm. In the example embodiment of FIG. 1, the cavity extends a height of approximately 500 micrometers from the membrane 140 to a base of the mesa 125. The mesa 125 has a cross-sectional width of approximately 290 micrometers. The laser has a thickness extending from the mesa 125 in a direction towards the membrane 140 of approximately 100 micrometers. A gap between the membrane 140 and the radiation-emitting surface 110 of the laser 105 is 50 micrometers or less. An overall cross-sectional width of the acoustic sensor 100 may be between 2.4 and 1.4 millimeters.

It will be appreciated that such dimensions are for purposes of example only. Thus, it will be understood that embodiments with dimensions that may generally be comparable to, yet individually or collectively vary from, those of the embodiment of FIG. 1, will also fall within the scope of the disclosure.

In use, an acoustic wave incident upon the membrane 140 will cause a vibration in the membrane 140. Radiation emitted from the laser 105 is reflected from the reflector 160 back into the laser 105 to produce a self-mixing effect, where the self-mixing effect is modulated by the vibrations of the membrane 140. Said self-mixing effect causes detectable variations in a junction voltage of the laser 105. As such, the junction voltage of the laser 105 corresponds to the acoustic wave due to the self-mixing interference effect. In some embodiments the acoustic sensor 100 may comprise, or may be coupled to, circuitry configured to sense the junction voltage of the laser 105. Specifically, in some embodiments, the laser 105 may comprise, or may be coupled to, circuitry configured to sense the junction voltage of the laser 105.

FIG. 2 depicts a cross-sectional view of an acoustic sensor 200 according to a second embodiment of the disclosure. The acoustic sensor 200 comprises a laser 205. In the example embodiment of FIG. 2, the laser 205 is a vertical-cavity surface emitting laser (VCSEL). It will be appreciated that in other embodiments, other laser diodes may be implemented.

The laser 205 is configured to emit radiation from a radiation-emitting surface 210 at a front of the laser 205, relative to a rear surface of the laser 205 comprising contacts 215 for providing electrical connectivity to the laser 205.

The acoustic sensor 200 comprises a first substrate 220. The first substrate 220 comprises a recess 290. In some embodiments, the recess 290 may be formed as a trench. The recess 290 is formed to comprise a mesa 225. The mesa 225 is configured to support the laser 205. In some embodiments, the laser 205 may be formed on the mesa 225. In other embodiments, the laser 205 is provided as a discrete device which is adhered to the mesa 225 during an assembly proves. The recess 290 may, for example, be formed by etching the first substrate 220. Electrical contacts (not shown), formed from conductive traces and/or vias may be provided in the first substrate 220 to supply electrical current to the laser 205 and/or to provide means to sense a junction voltage of the laser 205, as described below in more detail.

The first substrate 220 may comprise glass, silicon, or the like.

The acoustic sensor 200 also comprises a second substrate 230. The second substrate 230 is formed with an aperture 235, such that the acoustic sensor 200 may be assembled with the aperture 235 aligned with the recess 290.

The acoustic sensor 200 may be assembled with the mesa 225 of the first substrate 220 disposed within the second aperture 235.

The second substrate 230 may comprise glass, silicon, or the like.

The acoustic sensor 200 also comprises a membrane 240. The membrane 240, and associated reflector 260 and pressure equalization holes 255, are generally similar to the membrane 140, reflector 160 and pressure equalization holes 155 respectively of FIG. 1, and are not described in further detail for purposes of brevity.

In some embodiments, the second substrate 230 may be a silicon substrate. In some embodiments, the second substrate 230 may comprise a layer 250 of silicon dioxide, and the membrane 240 may be secured to the layer 250 of silicon dioxide.

The membrane 240 and the second substrate 230 may be provided as an assembly that is coupled, e.g. adhered, to the first substrate 220 during a process of assembly of the acoustic sensor 200.

Similar to the example embodiment of FIG. 1, the second embodiment of FIG. 2 also comprises a cavity 245 separating the membrane 240 from the laser 205 and extending rearward of the radiation-emitting surface 210 of the laser 205. A majority volume of the cavity 245 is disposed rearward of the radiation-emitting surface 210 of the laser 205.

The example dimensions of the embodiments of FIG. 1 and FIG. 2 are generally similar, and therefore also not described in more detail.

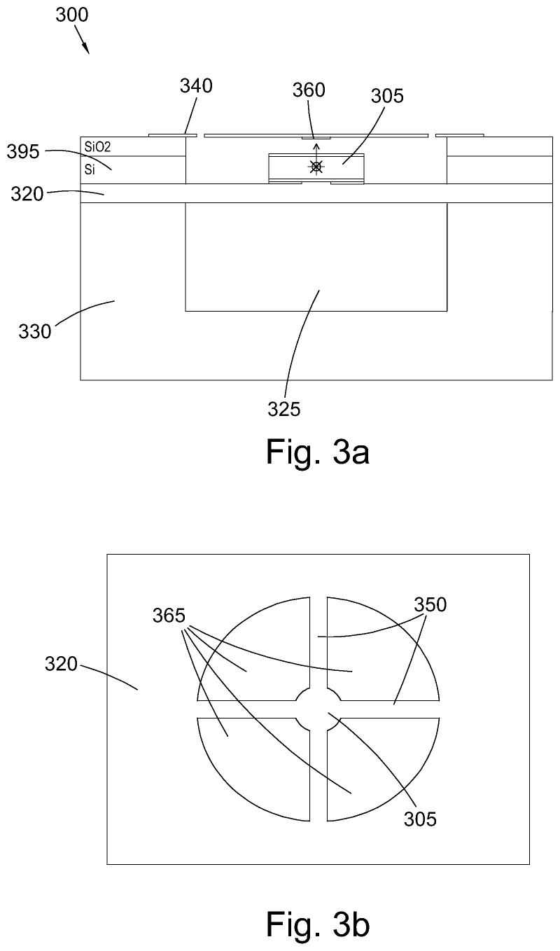

FIG. 3a depicts a cross-sectional view of an acoustic sensor 300 according to a third embodiment of the disclosure. Similar to the acoustic sensors 100, 200 of FIGS. 1 and 2, the acoustic sensor 300 comprises a laser 305 and a membrane 340, wherein the membrane comprises a reflector 360.

The acoustic sensor 300 comprises a first substrate 320. The first substrate 320 is configured to support the laser 305. The first substrate 320 may comprise glass, silicon, or the like. The first substrate 320 is an apertured substrate.

The acoustic sensor 300 also comprises a second substrate 330. The second substrate 330 is formed with a recess 325. The recess 325 may, for example, be formed by etching the second substrate 330. The second substrate 330 may comprise glass, silicon, or the like.

The acoustic sensor 300 comprises a third substrate 395. The third substrate 395 is configured to support the membrane 340.

The acoustic sensor 300 is assembled such that the first substrate 320 is disposed between the second substrate 330 and the third substrate 395, such that openings, e.g. apertures 365 in the first substrate 320 are aligned with the recess 325 in the second substrate, and the laser 305 is supported by the first substrate 320 between the second substrate 330 and the third substrate 395.

The recess 325 and a gap between the laser 305 and the membrane 340 define a cavity. A first portion of the cavity is between the membrane 340 and the first substrate 320 and a second portion of the cavity is defined by the recess 325 in the second substrate 330, wherein the first portion is communicably coupled to the second portion by the apertures 365 in the first substrate 320.

That is, the laser 305 is suspended or supported between the membrane 340 and a portion of the cavity that is rearward of the laser, by the apertured first substrate 320.

Advantageously, the absence of a mesa on the second substrate 330, when compared to the example embodiments of FIGS. 1 and 2, enables a volume of the cavity formed by the recess 325 to be relatively large, thereby increasing an acoustic capacitance of the cavity when compared to that of the embodiments of FIGS. 1 and 2.

FIG. 3b depicts a top view of the first substrate 320 as implemented in the third embodiment depicted in FIG. 3a. The first substrate 320 comprises the plurality of apertures 365. For purposes of example, four apertures 365 are depicted, although it will be appreciated that in other embodiments fewer than or greater than four apertures 365 may be implemented The apertures 365 are formed between a central portion for supporting the laser 305 and an outer portion, wherein the central portion is coupled to the outer portion by spokes 350. The apertures may be formed in the substrate by etching, or the like.

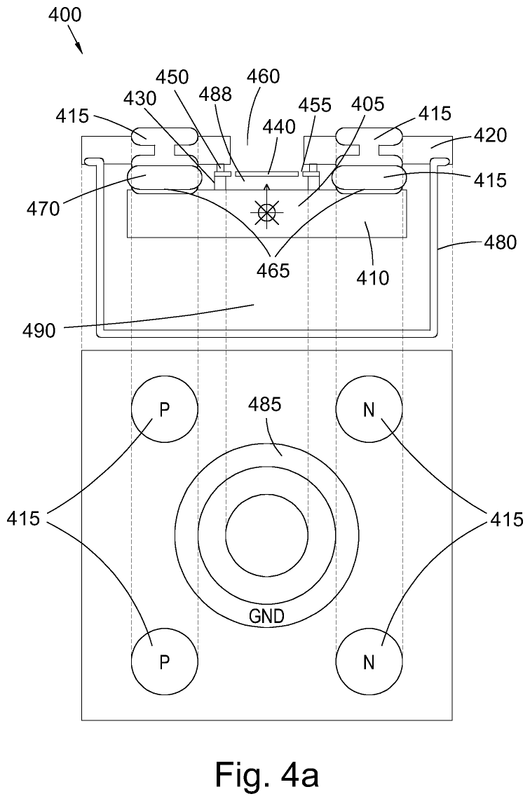

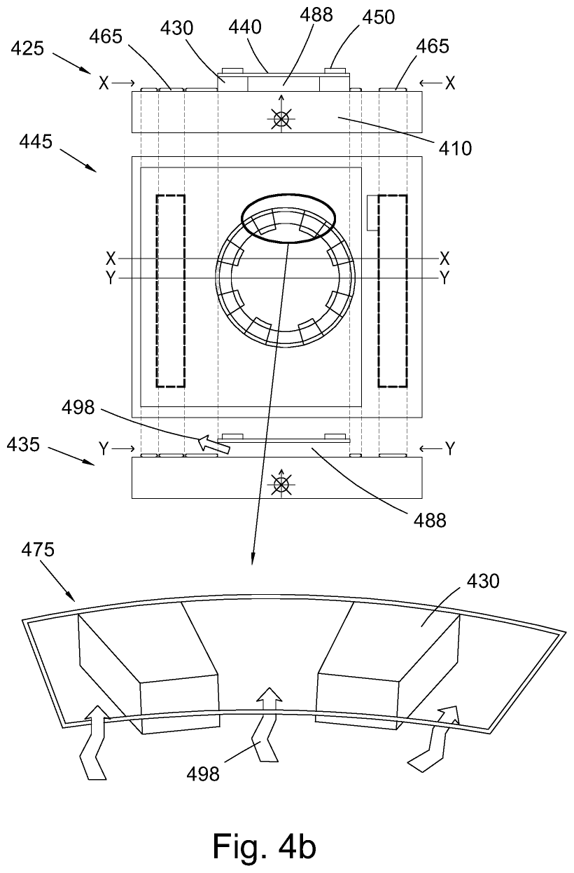

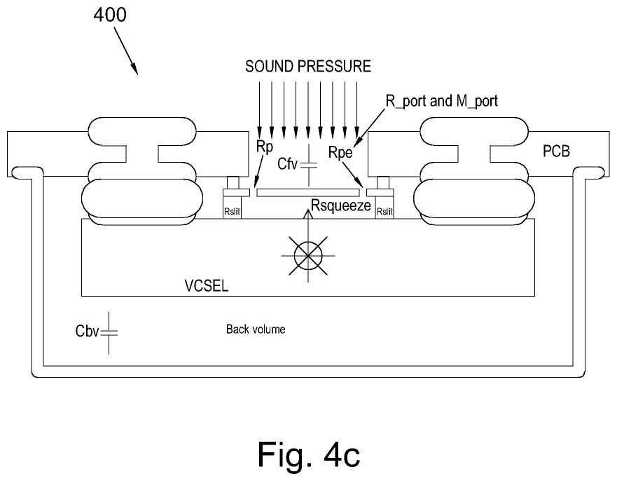

FIG. 4a depicts a cross-sectional view of an acoustic sensor 400 according to a fourth embodiment of the disclosure.

The acoustic sensor 400 comprises a laser 405. In the example embodiment of FIG. 4a, the laser 405 is a VCSEL. It will be appreciated that in other embodiments, other laser diodes may be implemented.

The laser 405 is configured to emit radiation from a radiation-emitting surface 410 of the laser 405. The laser 405 also comprises comprising terminals 465 for providing electrical connectivity to the laser 405.

The acoustic sensor 400 comprises a first substrate 420. The first substrate 420 may be a printed circuit board (PCB) substrate, such as an FR-4 substrate or the like. The first substrate comprises electrical contacts 415. In the example embodiment of FIG. 4a, the electrical contacts 415 are provided as vias, e.g. conductive elements extending through the first substrate 420.

The electrical contacts 415 of the first substrate 420 are conductively coupled to the terminals 465 of the laser 405. In the example embodiment of FIG. 4a, a conductive adhesive 470 is used to couple the electrical contacts 415 to the terminals 465. It will be appreciated that in other embodiments, the electrical contacts 415 may be soldered or otherwise conductively coupled to the terminals 465.

The acoustic sensor 400 comprises a membrane 440. The membrane is supported between the first substrate 420 and the laser 405 by a first support structure 430 and a second support structure 450. The first support structure 430 couples the membrane to the laser 405. The second support structure 450 couples the membrane 440 to the first substrate 420. The first support structure 430 supports the membrane 440 such that a first cavity portion 488 is provided between the membrane 440 and the radiation-emitting surface 410 of the laser 405. The first support structure 430 is configured to communicably couple the first cavity portion 488 to a second cavity portion 490, as described in more detail below with reference to FIG. 4b.

The membrane 440 also comprises pressure equalization holes 455, which serve the same purposes as those described in respect of the embodiment of FIG. 1 above. Although not shown in FIG. 4a, the membrane 440 also comprises a reflector, as described above with reference to FIG. 1.

The second support structure 450 supports the membrane 440 between an aperture 460 in the first substrate 420 and the radiation-emitting surface of the laser 405. As such, in use an acoustic wave may propagate through the aperture 460 in the first substrate 420 to be incident upon the membrane 440.

The laser 405, the membrane 440, the first support structure 430 and the second support structure 450 may be provided as an VCSEL assembly, which is assembled with the enclosure 480 and the first substrate 420 during an acoustic sensor 400 assembly process.

The acoustic sensor 400 comprises an enclosure 480. The enclosure 480 is acoustically sealed to the first substrate 420. For example, in some embodiments, the enclosure 480 is sealed to the first substrate using a sealing ring or gasket disposed between the enclosure 480 and the first substrate 420. In some embodiments the acoustic seal may be formed from an adhesive. In some embodiments, the enclosure 480 may be soldered to the first substrate 420 to form the acoustic seal.

The enclosure 480 is implemented as a can package. For example, in some embodiments the enclosure 480 is implemented as a metal can package.

The enclosure 480 encloses the laser 405, and as such the enclosure defines the second cavity portion 490.

Also shown in FIG. 4a is a corresponding top view of the acoustic sensor 400 according to a fourth embodiment of the disclosure. The top view shows the first substrate 420 comprising an aperture 460, through which the membrane 440 is visible. Also depicted are the electrical contacts 415 of the first substrate 420, which are conductively coupled to the terminals 465 of the laser 405 as described above. For purposes of example, four electrical contacts 415 are depicted, arranged in pairs labelled “N” and “P”. The electrical contacts 415 labelled “N” are coupled to an “N” terminal of the laser 405, e.g. a cathode, and the electrical contacts 415 labelled “P” are coupled to an “P” terminal of the laser 405, e.g. an anode. In the example of FIG. 4a, each pair of terminals provides a terminal for supplying electrical current to the laser 405 and a corresponding terminal for measuring a junction voltage of the laser 405. It will be appreciated that, in other embodiments, there may be as few as one “N” terminal and one “P” terminal.

Also depicted in the top view is a further terminal 485. In some embodiments, the further terminal 485 provides a ground connection from the first substrate 420 to a base or substrate of the laser 405.

FIG. 4b depicts a first cross sectional view 425, a second cross sectional view 435, a top view 445, and a partial perspective view 475 of the VCSEL assembly for use in the acoustic sensor 400 according to the fourth embodiment of the disclosure.

The top view 445 of the VCSEL assembly depicts the laser 405 with terminals 465 disposed at an upper surface, wherein the terminals 465 are for conductively coupling the laser 405 to the electrical contacts 415 of the first substrate 420.

Also depicted is the first support structure 430. The first support structure 430 is provided as a plurality of support elements. The membrane 440 is supported between the support elements of the first support structure 430 and the second support structure 450.

The first cross sectional view 425 depicts a cross section along the line denoted X-X in the top view 445. The first cavity portion 488 is provided between the membrane 440 and the radiation-emitting surface 410 of the laser 405, wherein the membrane 440 is supported by the support elements of the first support structure 430. In contrast, the second cross sectional view 435 depicts a cross section along the line denoted Y-Y in the top view 445. It can be seen in the second cross sectional view 435 that gaps between the plurality of support elements of the first support structure 430 enable airflow 498 to and from the first cavity portion 488.

This is more clearly shown in the partial perspective view 475 of the VCSEL assembly, wherein airflow 498 between the plurality of support elements of the first support structure 430 is depicted.

FIG. 4c depicts a further cross-sectional view of the acoustic sensor 400 according to the fourth embodiment of the disclosure. FIG. 4c is annotated with equivalent impedances, which may be considered when assessing the effects of features of the particular construction of the acoustic sensor 400. For example:
R_port: a resistance corresponding to a component of an acoustic impedance to compression of air in the aperture 460 in the first substrate 420;
M_port: an inductance corresponding to a component of an acoustic impedance to compression of air in the aperture 460 in the first substrate 420;
C_{fv}: a capacitance corresponding to an acoustic capacitance of the front volume, e.g. the first cavity portion 488;
R_{squeeze}: a resistance corresponding to a resistance of air in the first cavity portion 488 between the laser 405 and the membrane 440 to compression;
Rₛᵢₗₜ: a resistance corresponding to a resistance of air between the laser 405 and the membrane 440 to flow through the gaps between the support elements of the first support structure 430;
Rₚₑ: a resistance corresponding to a resistance of air to flow through the pressure equalization holes in the membrane 440, and wherein Rₚₑ is substantially larger in magnitude than a series combination of R_{squeeze} and Rₛᵢₗₜ; and
C_{bv}: a capacitance corresponding to an acoustic capacitance of the back volume, e.g. the second cavity portion 490 formed by the enclosure 480 enclosing the laser 405.

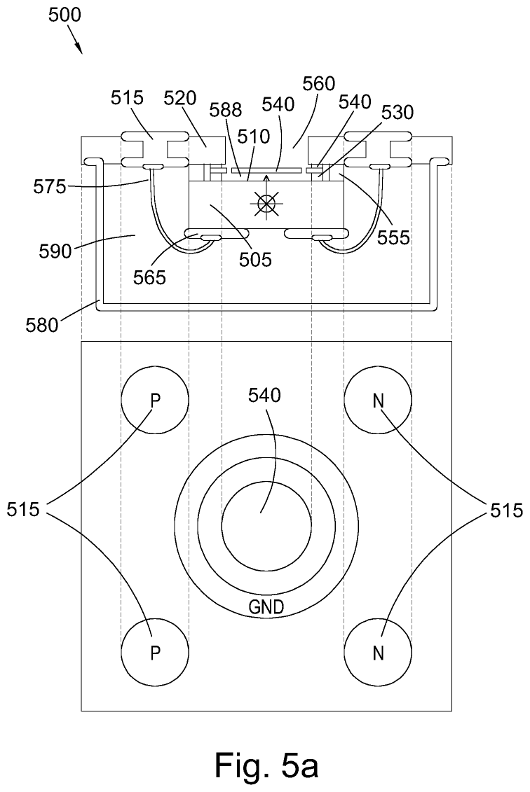

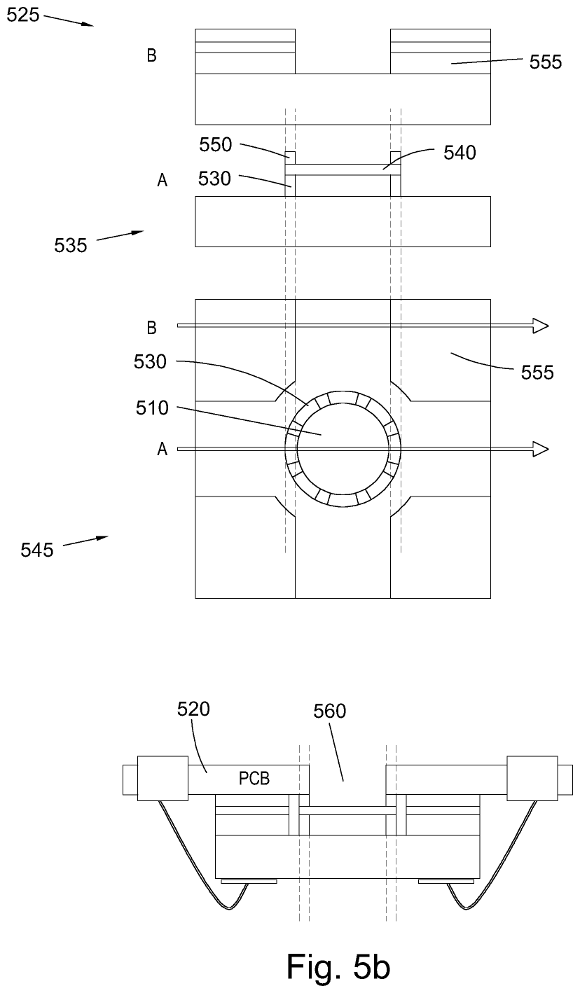

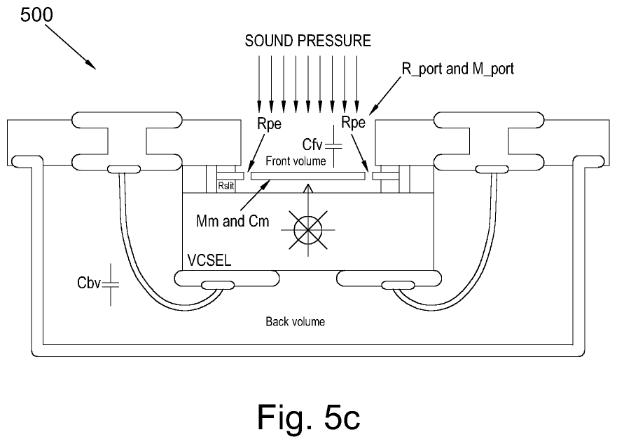

The particular dimensions of the construction of the acoustic sensors 400 of FIG. 4c ensure that R_{squeeze} and Rₛₗᵢₜ provide adequate damping, thus giving a sufficient acoustical response. Furthermore, the values of R_{squeeze} and Rₛᵢₗₜ are selected to also provide a relatively low acoustical noise. FIG. 5a depicts a cross-sectional view and a corresponding top view of an acoustic sensor 500 according to the fifth embodiment of the disclosure.

The acoustic sensor 500 comprises a laser 505. In the example embodiment of FIG. 5a, the laser 505 is a VCSEL.

Features of the acoustic sensor 500, such as the enclosure 580, the first substrate 520, the electrical contacts 515 of the first substrate 520, and the membrane 540 are generally comparable to that of the embodiment of FIG. 4a, and therefore are not described in further detail.

In contrast to the fourth embodiment of the acoustic sensor 400 which comprises a “top-emitting” VCSEL laser 405, the fifth embodiment of the acoustic sensor 500 comprises a “bottom-emitting” VCSEL laser 505. That is, the VCSEL is configured to emit radiation through the substrate that the laser is formed on, e.g. though an opposite side of the laser 505 than the side comprising the terminals 565 for providing electrical connectivity to the laser 505.

Furthermore, the terminals 565 of the laser 505 are connected to the electrical contacts 515 of the first substrate 520 by bondwires 570.

The membrane 540 is supported between the first substrate 520 and the laser 505 by a first support structure 530 and a second support structure 550. The first support structure 530 couples the membrane 540 to the laser 505. The second support structure 550 couples the membrane 540 to the first substrate 520. The first support structure 530 supports the membrane 540 such that a first cavity portion 588 is provided between the membrane 540 and a radiation-emitting surface 510 of the laser 505. The first support structure 530 is configured to communicably couple the first cavity portion 588 to a second cavity portion 590, as described in more detail below with reference to FIG. 5b.

The second support structure 550 supports the membrane 540 between an aperture 560 in the first substrate 520 and the radiation-emitting surface of the laser 505. As such, in use an acoustic wave may propagate through the aperture 560 in the first substrate 520 to be incident upon the membrane 540.

The laser 505, the membrane 540, the first support structure 530 and the second support structure 550 may be provided as a VCSEL assembly, which is assembled with the enclosure 580 and the first substrate 520 during an acoustic sensor 500 assembly process.

The acoustic sensor 500 also comprises a third support structure 555. The third support structure 555 couples the laser 505 to the first substrate 520, and is also configured to communicably couple the first cavity portion 588 to a second cavity portion 590, as described in more detail below with reference to FIG. 5b. In some embodiments, the third support structure 555 may be provided or formed as part of, or together with, the first support structure 530. In some embodiments, the third support structure 555 may be provided or formed as part of, or together with, the second support structure 550. The third support structure 555 provides structural support to the acoustic sensor 500.

FIG. 5b depicts a first cross sectional view 525, a second cross sectional view 535 and a top view 545 of a VCSEL assembly for use in an acoustic sensor according to a fifth embodiment of the disclosure, and a further representation of a cross-section the acoustic sensor 500.

The top view 545 of the VCSEL assembly depicts the laser 505 coupled to the first support structure 530 and the third support structure 555.

The first support structure 530 is provided as a plurality of support elements. The membrane 540 is supported between the support elements of the first support structure 530 and the second support structure 550.

In some embodiments, the first support structure 530 is formed from an epoxy, or a photoresist material such as SU-8 or the like. In some embodiments, the first support structure 530 may be formed using a lithographic process.

The third support structure 555 is also provided as a plurality of elements, arranged to form a cruciform trench arrangement generally centered around the first support structure 530.

In some embodiments, a total height of the third support structure 555, e.g. a distance from the radiation-emitting surface 510 of the laser 505 to the first substrate 520, is in the region of 16 micrometers.

In some embodiments, a total height of the first support structure 530, e.g. a distance from the radiation-emitting surface 510 of the laser 505 to the membrane 540, is in the region of 12 micrometers.

The first cross sectional view 525 depicts a cross section along the line denoted A in the top view 545. The first cavity portion 588 is provided between the membrane 540 and the radiation-emitting surface 510 of the laser 505, wherein the membrane 540 is supported by the plurality of support elements of the first support structure 530.

The second cross sectional view 535 depicts a cross section along the line denoted B in the top view 545. It can be seen in the second cross sectional view 535 that a trench between the plurality of support elements of the third support structure 555 enable airflow to and from the first cavity portion 588. A corresponding representation of a cross-section the acoustic sensor 500 is also depicted.

FIG. 5c depicts a further cross-sectional view of the acoustic sensor 500 according to the fifth embodiment of the disclosure. Similar to the embodiment of FIG. 4c, the particular dimensions of the construction of the acoustic sensor 500 of FIG. 5c ensures that R_{squeeze} and Rₛₗᵢₜ provide adequate damping, thus providing a sufficient acoustical response. Furthermore, the values of R_{squeeze} and Rₛₗᵢₜ are selected to also provide a relatively low acoustical noise.

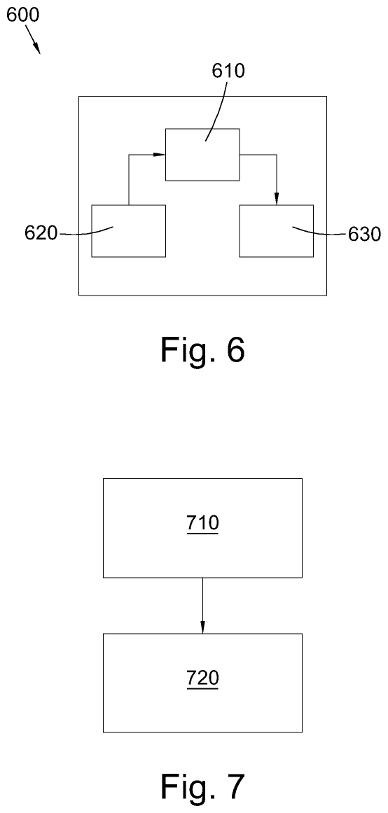

FIG. 6 depicts an apparatus 600 comprising an acoustic sensor 610 according to an embodiment of the disclosure. The acoustic sensor 600 may be an acoustic sensor 100, 200, 300, 400, 500 as described with reference to FIGS. 1 to 5d. The apparatus 600 is depicted as a generic apparatus and may correspond to, for example, a smart speaker; a smart phone; a smart-watch; a laptop, a tablet device; or headphones.

The apparatus 600 comprises a laser driver 620. The laser driver 620 may be configured to provide an electrical current to drive a laser of the acoustic sensor 610.

The apparatus 600 also comprises sensor circuitry 630. The sensor circuitry 630 of configured to sense a junction voltage of a laser of the acoustic sensor 610. As such, the sensor circuitry 630 may be configured to determine characteristics of an acoustic wave incident upon the acoustic sensor 620. The sensor circuitry 630 may, for example, comprise an analogue to digital converter. The sensor circuitry 630 may be coupled to, or integrated with, processing circuitry (not shown).

It will be appreciated that, in some embodiments, the laser driver 620 and the sensor circuitry 630 may be integrated into a single device.

FIG. 7 depicts a method of manufacturing an acoustic sensor 100, 200, 300, 400, 500, 600 according to an embodiment of the invention. The method comprising a step 710 of providing a laser and a membrane in a package such that the membrane is configured to vibrate in the presence of an acoustic wave and to reflect radiation emitted by the laser back toward the laser to produce a self-mixing interference effect corresponding to the acoustic wave.

The method also comprises a step 720 of providing the package with a cavity separating the membrane from the laser and extending rearward of a radiation-emitting surface of the laser, a majority volume of the cavity being disposed rearward of the radiation-emitting surface of the laser.

It will be understood that the above description is merely provided by way of example, and that the present disclosure may include any feature or combination of features described herein either implicitly or explicitly of any generalisation thereof, without limitation to the scope of any definitions set out above. It will further be understood that various modifications may be made within the scope of the disclosure.

1. An acoustic sensor comprising:
a laser;
a membrane configured to:
vibrate in the presence of an acoustic wave; and
reflect radiation emitted by the laser back toward the laser to produce a self-mixing interference effect corresponding to the acoustic wave;
and a cavity separating the membrane from the laser and extending rearward of a radiation-emitting surface of the laser, a majority volume of the cavity being disposed rearward of the radiation-emitting surface of the laser,
wherein a gap between the membrane and the radiation-emitting surface of the laser is 50 micrometers or less, and
wherein the laser is configured such that a junction voltage of the laser corresponds to the acoustic wave due to the self-mixing interference effect.

2. (canceled)

3. (canceled)

4. The acoustic sensor of claim 1 comprising circuitry coupled to the laser and configured to sense the junction voltage.

5. The acoustic sensor of claim 1 comprising a first substrate, the laser electrically coupled to, formed on, or mounted on the first substrate.

6. The acoustic sensor of claim 5, wherein the membrane is disposed between an aperture in the first substrate and the radiation-emitting surface of the laser.

7. The acoustic sensor of claim 5, comprising an enclosure acoustically sealed to the first substrate and enclosing the laser, wherein the enclosure defines the cavity.

8. The acoustic sensor of claim 5, wherein the substrate comprises a recess surrounding the laser and defining the cavity, or a mesa supporting the laser and at least in part defining the cavity.

9. The acoustic sensor of claim 5, wherein the first substrate is coupled to a second substrate, a first portion of the cavity being between the membrane and the first substrate and a second portion of the cavity being defined by a recess in the second substrate, wherein the first portion is communicably coupled to the second portion by at least one opening in the first substrate.

10. The acoustic sensor of claim 1, wherein the laser is suspended or supported between the membrane and a portion of the cavity that is rearward of the laser, by an apertured substrate.

11. The acoustic sensor of claim 1 wherein the laser is a vertical cavity surface-emitting laser.

12. The acoustic sensor of claim 1 wherein the membrane comprises a stretched film provided under tension.

13. The acoustic sensor of claim 1 wherein the membrane comprises a reflector for reflecting radiation emitted by the laser, wherein a diameter of the reflector is less than 100 micrometers.

14. An apparatus comprising the acoustic sensor of claim 1, wherein the apparatus is one of: a smart speaker; a smart phone; a smart-watch; a laptop, a tablet device; or headphones.

15. A method of manufacturing an acoustic sensor, the method comprising:
providing a laser and a membrane in a package such that the membrane is configured to vibrate in the presence of an acoustic wave and to reflect radiation emitted by the laser back toward the laser to produce a self-mixing interference effect corresponding to the acoustic wave; and
providing the package with a cavity separating the membrane from the laser and extending rearward of a radiation-emitting surface of the laser, a majority volume of the cavity being disposed rearward of the radiation-emitting surface of the laser.
